(19) United States
(12) Patent Application Publication
(10) Pub. No.: US 2026/0143881 A1
(43) Pub. Date: May 21, 2026

(54) ENCIRCLED ULTRA-SMALL CHIP ON BOARD FLIP-CHIP HIGH-VOLTAGE FIVE-COLOR LIGHT SOURCE

(71) Applicant: SHEN ZHEN MAIKE OPTO-ELEC TRONICS. CO., LTD, Shenzhen, Guangdong (CN)

(72) Inventor: Yong Liu, Shenzhen (CN)

(21) Appl. No.: 19/271,629

(22) Filed: Jul. 16, 2025

(30) Foreign Application Priority Data
Nov. 19, 2024 (CN) 202422793190.9

(51) Int. Cl. H10H 29/34; H10H 29/85

(52) U.S. Cl. CPC H10H 29/34; H10H 29/8506

(57) ABSTRACT

Disclosed is an encircled ultra-small chip on board (COB) flip-chip high-voltage five-color light source. The five-color light source includes a substrate, pure warm white chips and red, green, blue (RGB) chips. The substrate adopts a cup-in-cup structure, which includes a circular boss, a first layout area located in the circular boss and a second layout area located on a periphery of the circular boss; and the pure warm white chips and the RGB chips are arranged in the first layout area and the second layout area. In the present disclosure, problems of non-uniform color and non-uniform light spots and brightness during secondary optical color mixing can be solved, and the colorfulness and light gathering effect of the light source are improved.

### CROSS-REFERENCE TO RELATED APPLICATION

This application claims priority of Chinese Patent Application No. 202422793190.9, filed on Nov. 19, 2024, the entire contents of which are incorporated herein by reference.

### TECHNICAL FIELD

The present disclosure relates to the technical field of photoelectricity, and in particular relates to an encircled ultra-small chip on board (COB) flip-chip high-voltage five-color light source.

### BACKGROUND

Light-emitting diode (LED) light source is a commonly used type of light source at present, which has different lamp bead types according to different application occasions, mainly due to the different types of LED brackets used, which result in different LED types. Specific classification includes: through-hole brackets, surface mount device (SMD) brackets, high-power brackets, flat brackets and COB brackets. Since the LED bracket needs to be electrically and thermally conductive, metal will be used as the conductive connection material. At the same time, some areas need to be insulated, which requires the use of engineering plastics. Therefore, the general LED bracket is formed by metal stamping and injection molding. Various LEDs with different powers use different support materials. Low-power LEDs generally use polyphthalamide (PPA), medium-power LEDs generally use polycyclohexylene dimethylene terephthalate (PCT). Currently, some high-power LEDs are made of epoxy molding compound (EMC) or ceramic substrate materials.

Currently, there are three-color, four-color, five-color or more color lamp beads on the market. Generally, the hardware is first stamped, silver-plated, and injection-molded with PPA, PCT and other plastic materials. Red green blue (RGB) lamp beads are generally electroplated with a copper material, stamped into a required size, and injection molded to form a bracket; and RGB chips are fixed and welded at a middle position in a bowl of the bracket to form RGB lamp beads, which are distributed side by side, with warm white parts placed on two sides, as shown in FIG. 1(a). In addition, for the existing COB multi-color LED beads, generally, there is no isolation between the RGB chips and the white light chips. However, this design method has the following disadvantages.
1. RGB is placed in the middle of a cup of a bracket, and a multi-chip is distributed side by side in series. When a lens is mounted and the secondary optical mixed color lights up, one side is bluish and the other side is greenish, as shown in FIG. 2, resulting in uneven color mixing of light spots during RGB color mixing, which has a serious impact on visual effects and aesthetics.
2. Pure white and warm white are placed on two sides of the lamp beads, and when pure white and warm white are lit together, the light spots and brightness on two sides will be different, thereby affecting the beauty and failing to achieve the effect of uniform color.
3. In the existing multi-color lamp beads of COB mode, the RGB chips and the pure warm white chips are not isolated. Since the surface of the white light chip is arranged with fluorescent powder material, the penetration of blue light is relatively strong. Therefore, when the blue light is emitted, the blue light will penetrate through the fluorescent powder of the white light chips to change its color, the color purity of the blue light is greatly reduced, and the luminous efficacy of the emitted blue light cannot reach the effect, as shown in FIG. 1(b).
4. The existing COB type multi-color lamp beads are relatively large in size, which cannot meet the requirements for small-size fields.

### SUMMARY

The present disclosure aims to solve one of the above technical problems in the related art at least to a certain extent.

Therefore, an objective of the present disclosure is to provide an encircled ultra-small COB flip-chip high-voltage five-color light source, which can solve the problems of non-uniform color and non-uniform light spot and brightness occurring during secondary optical color mixing, and improve the colorfulness and light gathering effect of the light source.

In order to solve the above technical problems, the present disclosure is implemented as follows.

An example of the present disclosure provides an encircled ultra-small COB flip-chip high-voltage five-color light source, including a substrate, pure warm white chips and RGB chips;
the substrate adopts a cup-in-cup structure, which includes a circular boss, a first layout area located in the circular boss and a second layout area located on a periphery of the circular boss; the second layout area surrounds the periphery of the circular boss in 360°, and the circular boss physically isolates the first layout area and the second layout area; and
the pure warm white chips and the RGB chips are arranged in the first layout area 1 and the second layout area.

In addition, according to the encircled ultra-small COB flip-chip high-voltage five-color light source of the present disclosure, the following additional technical features are as follows.

In some embodiments, the RGB chips are arranged in the first layout area, and the pure warm white chips are arranged in the second layout area.

In some embodiments, blue light chips of the RGB chips are arranged in a middle of the first layout area, and green light chips and red light chips of the RGB chips are arranged around the blue light chip in sequence; and
upper and lower sides and/or left and right sides of a layout area of the blue light chips are arc-shaped, and a layout area of the green light chips and a layout area of the red light chips are several arc-shaped segments.

In some embodiments, the blue light chips in the RGB chips are arranged on one side of the first layout area, and the green light chips and the red light chips in the RGB chips are arranged on side perimeters of the blue light chips in a side embracing manner in sequence; and
a side of the layout area of the blue light chips close to the green light chips is arc-shaped, and the layout area of the green light chips and the layout area of the red light chips are arc-shaped.

In some embodiments, the pure warm white chips are arranged in a circle shape in the second layout area, and pure white chips and warm white chips in the pure warm white chips are arranged alternately with each other.

In some embodiments, the RGB chips are arranged in the second layout area, and the pure warm white chips are arranged in the first layout area.

In some embodiments, the blue light chips in the RGB chips are arranged in an inner ring of the second layout area in a circle shape, and the green light chips and the red light chips in the RGB chips are arranged on peripheries of the blue light chips in a circle shape.

In some embodiments, the green light chips and the red light chips are alternately arranged to form a circle and arranged on the peripheries of the blue light chips.

In some embodiments, the green light chips and the red light chips each form a circle and are arranged on the peripheries of the blue light chips in sequence.

In some embodiments, the pure white chips and the warm white chips in the pure warm white chips are arranged in semicircular shapes in the first layout area, or:
the pure white chips and the warm white chips are evenly arranged in the first layout area 1 in an alternating arrangement manner.

Compared with the related art, the present disclosure has at least the following beneficial effects.

In the encircled ultra-small COB flip-chip high-voltage five-color light source provided by the example of the present disclosure, by setting the circular boss, the physical isolation between the RGB area and the white light area is realized, thereby solving the problem of uneven color caused by insufficient purity of blue light color in the related art.

In the encircled ultra-small COB flip-chip high-voltage five-color light source provided by the example of the present disclosure, by setting the pure warm white chips in a uniform circular layout or placing the pure warm white chips in the middle of the substrate, the problem of uneven brightness during color mixing in the related art is solved.

In the encircled ultra-small COB flip-chip high-voltage five-color light source provided by the example of the present disclosure, by adopting the unique RGB layout mode, the problem of “negative and positive light spots” with one color on one side in color mixing in the related art is solved.

Additional aspects and advantages of the present disclosure will be set forth in part in the following description, and in part will become obvious from the following description, or may be learned by practice of the present disclosure.

### BRIEF DESCRIPTION OF THE DRAWINGS

FIG. 1(a) is an arrangement diagram of RGB lamp beads in the related art provided by the present disclosure;

FIG. 1(b) is a light source diagram when a purity of blue light color is insufficient in the related art provided by the present disclosure;

FIG. 2 is a secondary optical color mixing effect diagram of a multicolor light source in the related art provided by the present disclosure;

FIG. 3(a) is a schematic diagram of a solution 1of encircled layout of red light, green light and blue light chips provided by an example of the present disclosure;

FIG. 3(b) is a schematic diagram of a solution 2 of encircled layout of red light, green light and blue light chips provided by an example of the present disclosure;

FIG. 4 is a layout schematic diagram of pure warm white chips provided by an example of the present disclosure;

FIG. 5 is a layout schematic diagram of an encircled ultra-small COB flip-chip high-voltage five-color light source provided by an example of the present disclosure;

FIG. 6 is a layout schematic diagram of the encircled ultra-small COB flip-chip high-voltage five-color light source provided by the other example of the present disclosure; and

FIG. 7 is a layout schematic diagram of the encircled ultra-small COB flip-chip high-voltage five-color light source provided by another example of the present disclosure.

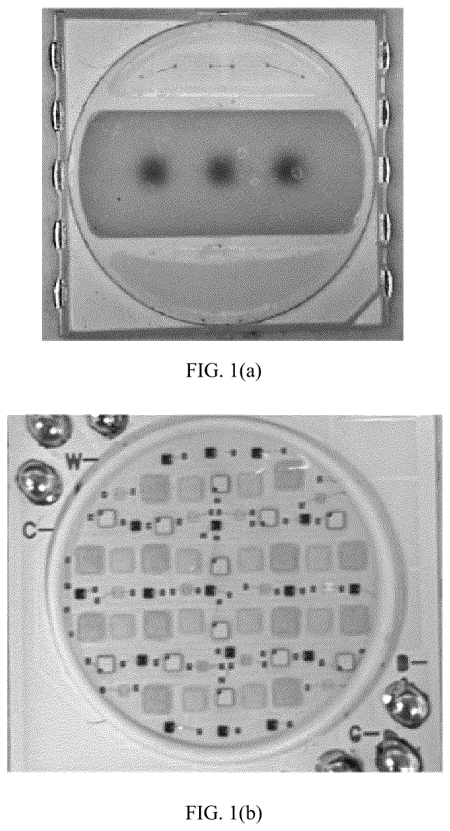

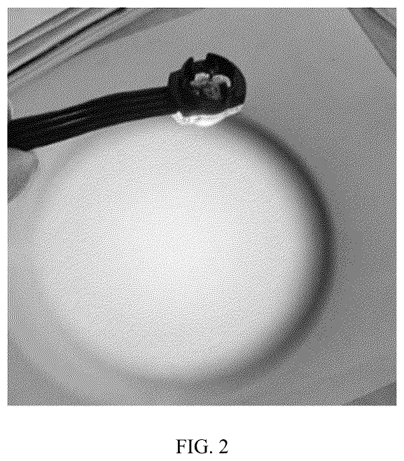

Reference numerals and denotations thereof:
1—first layout area; 2—second layout area; 3—circular boss; and 4—housing.

### DETAILED DESCRIPTION

The technical solutions in the examples of the present disclosure will be clearly and completely described below with reference to the accompanying drawings in the examples of the present disclosure. Obviously, all the described examples are only some, rather than all examples of the present disclosure. Based on the examples in the present disclosure, all other examples obtained by those ordinary skilled in the art without creative efforts belong to the protection scope of the present disclosure.

The examples of the present disclosure will be described in detail below through specific examples and application scenarios in conjunction with the accompanying drawings.

In some examples of the present disclosure, an encircled ultra-small COB flip-chip high-voltage five-color light source is provided, which is redesigned in view of the defects of the related art.

In some examples of the present disclosure, to solve the problem that when blue light is lit, the fluorescent powder passing through white light chips significantly reduces the purity of the blue color, a circular 360° boss is designed on a periphery of RGB chips by a way of cup-in-cup design. The circular boss 3 physically divides a substrate into two layout areas: a first layout area 1 located on an inner side of the circular boss 3 and a second layout area 2 located on a periphery of the circular boss 3. The first layout area 1 is a circular area, and the second layout area 2 is an annular area. The RGB chips and the pure warm white chips are arranged in the two layout areas, and the chips in the two areas are physically isolated by the circular boss 3. By designing in this way, the light in the RGB layout area can be well prevented from crossing with a layout area of the pure warm white chips, which solves the problem that the color purity mentioned above is greatly reduced and improves the color degree and uniformity.

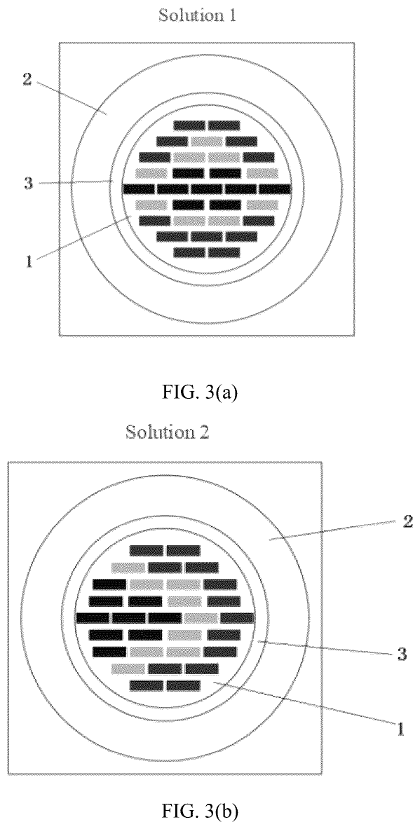

In some examples of the present disclosure, the chips of red light, green light and blue light are placed in the first layout area 1 in a middle of the substrate, and are distributed in an encircled manner, as shown in FIG. 3(a) and FIG. 3(b).

In the above examples, in the solution 1, blue light chips are arranged at a center, and the blue light chips are surrounded by green light chips, which is surrounded by upper and lower semi-rings. With such a design, the problem of “shaded and bright spots” with one color on one side existing in the secondary optics RGB color mixing can be perfectly solved, the light efficiency is the highest, and the uniformity and colorfulness are more perfect. Red light adopts the same design as blue-green light, red light chips surround the green light chips and the blue light chips in the middle. Through a design method of embracing layer by layer, when red light, green light, and blue light are mixed in pairs or three colors, resulting light spots can perfectly solve the problem of “shaded and bright spots”, and the light efficiency and color degree can achieve good results. The blue light chips, the green light chips and the red light chips are all arranged in the first layout area 1.

In another example of the present disclosure, as shown in the solution 2 in FIG. 3(b), the blue light chips are arranged in a middle region of the substrate, that is, one side of the first layout area 1, the green light chips are arranged around the periphery of the blue light chips from one side, the red light chips are also arranged around the side of the green light chips away from the blue lights in one side, and the blue, green and red chips have a circular arrangement shape as a whole. Through this design method, the problem of “shaded and bright spots” with one color on one side existing during secondary optics RGB color mixing can also be well solved, and the light efficiency, uniformity and colorfulness can all achieve good results. The blue light chips, the green light chips and the red light chips are all arranged in the first layout area 1.

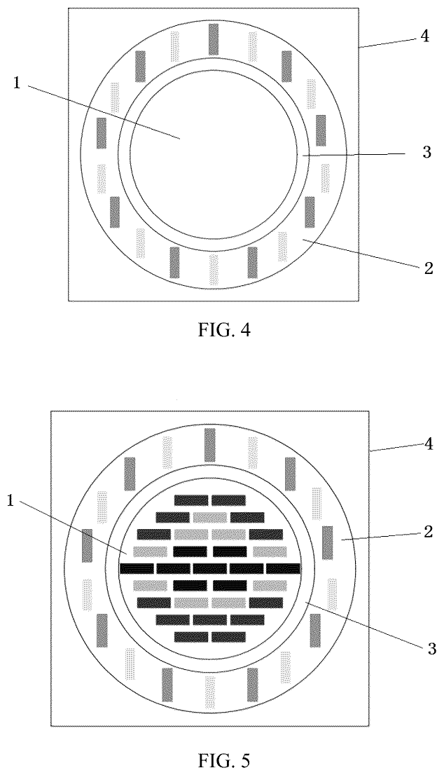

In some examples of the present disclosure, the pure white and the warm white are placed on two sides, resulting in the problem of uneven colors and inconsistent brightness on both sides when the secondary optics are lit together, causing one side to be bright and one side to be dark. In this example, the pure warm white chips are arranged in a 360° circle around the periphery of the RGB chip (that is, in the second layout area 2), and the pure white chips and the warm white chips are arranged alternately, as shown in FIG. 4, through this design method, the problems caused by one side being bright, one side being dark, uneven light spots and other problems caused when the pure warm white chips are lit together are perfectly solved, greatly improving the uniformity and colorfulness of the light spots, and achieving the highest light gathering effect. And through this 360° annular design, the light pattern emitted is a 360° area circular light emission, and the light efficiency and light gathering effect achieve good results.

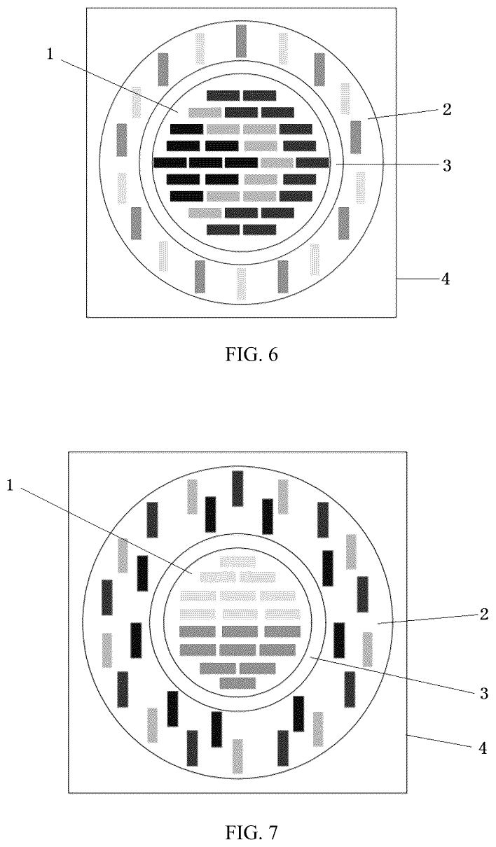

In the above examples, the arrangement method of the pure warm white chips can be combined with the arrangement method of the front RGB chips to form a new five-color light source design solution. The overall layout diagram when combined with the previous solution 1 is shown in FIG. 5, and the overall layout diagram when combined with the previous solution 2 is shown in FIG. 6.

In some examples of the present disclosure, referring to FIG. 7, the pure warm white chips are disposed in the first layout area 1, and the RGB chips are disposed in the second layout area 2. pure warm white chips are evenly arranged. Among the RGB chips, the blue light chips are circularly arranged around the periphery of the circular boss 3, the green light chips and the red light chips are circularly arranged around the periphery of the blue light chips, and the green light chips and the red light chips are arranged alternately at equal intervals. The blue light chips are also arranged at equal intervals.

In the above examples, a five-color LED light source in a COB manner is used, all chips are flip chips, and a multi-layer aluminum oxide or aluminum nitride ceramic substrate is used, which can achieve good heat dissipation and solve the heat dissipation problem. In addition, the chips can be connected by wiring on the substrate or in the substrate, which avoids various hidden dangers including short circuits and layout difficulties that may exist in open wire connections, and solves the wiring control problem. The size design of the entire product can also be further reduced due to the factors of wiring in the substrate, and the size of the finished product can also be designed to be between 4.5 mm*4.5 mm and 5.0 mm*5.0 mm according to the use of chips of different sizes. The design voltage of the finished product has three voltage levels of 18 V, 24 V, and 27 V. A multi-layer wiring structure is designed by using the excellent heat conduction, heat dissipation and insulation properties of the aluminum oxide or aluminum nitride ceramic substrate, thereby reducing the complicated wire bonding process of normal chips, greatly improving the utilization rate of the space, and achieving a small-size multi-color high-voltage COB flip-chip five-color light source. In this way, by reducing the size of the product, not only the light condensing effect and the color uniformity can be greatly improved in the secondary optics, but also the design difficulty of the secondary optics can be reduced, thereby achieving a better product design.

It is to be noted that, for a specific structure, a working principle, a connection manner to another component, a working manner, a control logic, and the like of each chromatic light chip, and a manufacturing process of the LED light source that is not explicitly described, reference may be made to the related art, which is not limited in this examples, and is not described in detail herein again.

Parts of the present disclosure that are not described in detail are well known to those skilled in the art.

The examples of the present disclosure have been described above with reference to the accompanying drawings. However, the present disclosure is not limited to the above specific embodiments. The above specific embodiments are merely illustrative and not restrictive. Under the enlightenment of the present disclosure, those skilled in the art can also make many forms without departing from the spirit of the present disclosure and the scope protected by the claims, which all belong to the protection of the present disclosure.

1. An encircled ultra-small chip on board (COB) flip-chip high-voltage five-color light source, comprising a substrate, pure warm white chips and red, green, blue (RGB) chips, wherein
the substrate adopts a cup-in-cup structure, which comprises a circular boss (3), a first layout area (1) located in the circular boss (3) and a second layout area (2) located on a periphery of the circular boss (3); the second layout area (2) surrounds the periphery of the circular boss (3) in 360°, and the circular boss (3) physically isolates the first layout area (1) and the second layout area (2); and
the pure warm white chips and the RGB chips are arranged in the first layout area (1) and the second layout area (2).

2. The encircled ultra-small COB flip-chip high-voltage five-color light source according to claim 1, wherein the RGB chips are arranged in the first layout area (1), and the pure warm white chips are arranged in the second layout area (2).

3. The encircled ultra-small COB flip-chip high-voltage five-color light source according to claim 2, wherein blue light chips of the RGB chips are arranged in a middle of the first layout area (1), and green light chips and red light chips of the RGB chips are arranged around the blue light chip in sequence; and
upper and lower sides and/or left and right sides of a layout area of the blue light chips are arc-shaped, and a layout area of the green light chips and a layout area of the red light chips are several arc-shaped segments.

4. The encircled ultra-small COB flip-chip high-voltage five-color light source according to claim 2, wherein the blue light chips in the RGB chips are arranged on one side of the first layout area (1), and the green light chips and the red light chips in the RGB chips are arranged on side perimeters of the blue light chips in a side embracing manner in sequence; and
a side of the layout area of the blue light chips close to the green light chips is arc-shaped, and the layout area of the green light chips and the layout area of the red light chips are arc-shaped.

5. The encircled ultra-small COB flip-chip high-voltage five-color light source according to claim 2, wherein the pure warm white chips are arranged in a circle shape in the second layout area (2), and pure white chips and warm white chips in the pure warm white chips are arranged alternately with each other.

6. The encircled ultra-small COB flip-chip high-voltage five-color light source according to claim 1, wherein the RGB chips are arranged in the second layout area (2), and the pure warm white chips are arranged in the first layout area (1).

7. The encircled ultra-small COB flip-chip high-voltage five-color light source according to claim 6, wherein the blue light chips in the RGB chips are arranged in an inner ring of the second layout area (2) in a circle shape, and the green light chips and the red light chips in the RGB chips are arranged on peripheries of the blue light chips in a circle shape.

8. The encircled ultra-small COB flip-chip high-voltage five-color light source according to claim 7, wherein the green light chips and the red light chips are alternately arranged to form a circle and arranged on the peripheries of the blue light chips.

9. The encircled ultra-small COB flip-chip high-voltage five-color light source according to claim 7, wherein the green light chips and the red light chips each form a circle and are arranged on the peripheries of the blue light chips in sequence.

10. The encircled ultra-small COB flip-chip high-voltage five-color light source according to claim 6, wherein the pure white chips and the warm white chips in the pure warm white chips are arranged in semicircular shapes in the first layout area (1), or:
the pure white chips and the warm white chips are evenly arranged in the first layout area (1) in an alternating arrangement manner.
